(19) United States
(12) Patent Application Publication
(10) Pub. No.: US 2026/0112529 A1
(43) Pub. Date: Apr. 23, 2026

(54) PROCESS CHAMBER WITH IN-SITU MAGNETIC ANNEALING AND BOW CONTROL

(71) Applicant: Applied Materials, Inc., Santa Clara, CA (US)

(72) Inventors: Jay Min SOH, Singapore (SG); Li Ying CHOO, Singapore (SG); Siew Kit HOI, Singapore (SG); Zhong Yaoying, Singapore (SG); Haomin XU, Singapore (SG); Xiao TAN, Singapore (SG)

(21) Appl. No.: 18/924,224

(22) Filed: Oct. 23, 2024

(51) Int. Cl. H01F 7/02; G05B 19/4099; H01L 21/324; H01L 21/67; H01L 21/687

(52) U.S. Cl. CPC H01F 7/0252; G05B 19/4099; H10P 72/0436; H10P 72/7618; H10P 95/90; G05B 2219/45031; H10P 72/7602

(57) ABSTRACT

A process chamber for fabricating a semiconductor is disclosed. In one aspect, the process chamber includes a chamber body defining a chamber volume. The process chamber also includes a pedestal having a heater arranged to heat a substrate disposed on the pedestal. The pedestal is movable within the chamber volume between a first position and a second position. When the pedestal is in the first position, the pedestal at least partially defines a process cavity in which the substrate is processed. The process chamber further includes a magnet coupled with the chamber body below the process cavity. With the pedestal in the second position and the heater heating the substrate, the magnet is arranged to expose the substrate to a magnetic field in-situ within the chamber volume.

### BACKGROUND

### Field

Embodiments of the present disclosure generally relate to physical vapor deposition (PVD) process chambers.

### Description of the Related Art

Physical vapor deposition (PVD) has long been used in depositing metals and other materials in the fabrication of semiconductor integrated circuits. PVD systems, or PVD chambers, typically include a magnetron positioned at the back of a target to project a magnetic field into a processing space to increase the density of plasma and enhance the sputtering rate. Typically, the magnetron is rotated about a center of the target to provide a more uniform erosion pattern of the target and deposition profile on the substrate.

PVD chambers can be used to form a magnetic film stack having magnetic and dielectric layers stacked on a base layer. As one example, a first PVD chamber can deposit a magnetic film onto a base layer, and this stack up can be removed from the first PVD chamber to be cooled. After cooling, the stack up can be moved to a second PVD chamber, which can deposit a dielectric film on the magnetic film. This stack up can be removed from the second PVD chamber and moved to a heat treatment chamber to heat the stack up. Compressive stresses on the films can cause bowing, and thus, before the stack up is returned to the first PVD chamber for the next magnetic layer, the stack up can be heated by the heat treatment chamber to reduce bowing and stress on the films. The stack up can be removed from the heat treatment chamber, cooled, and then returned to the first PVD chamber for the next magnetic layer. This process can iterate until the stack up is complete. Moreover, in one, some, or all iterations of the process, before the stack up is returned to the first PVD chamber for the next magnetic layer, the stack up can be moved to an ex-situ magnetic annealing tool to address magnetic coercivity and saturation of the magnetic layers of the stack up, which can align magnetic domains of the magnetic layers.

### SUMMARY

The present disclosure generally relates to a physical vapor deposition (PVD) process chamber having features that enable in-situ magnetic annealing and bow control management for magnetic film stacks, such as magnetic film stacks having alternating magnetic and dielectric layers stacked on a base layer.

In one aspect, a process chamber is provided. The process chamber includes a chamber body defining a chamber volume. The process chamber also includes a pedestal having a heater arranged to heat a substrate disposed on the pedestal, the pedestal being movable within the chamber volume between a first position and a second position, and, when the pedestal is in the first position, the pedestal at least partially defines a process cavity. Further, the process chamber includes a magnet coupled with the chamber body below the process cavity. With the pedestal in the second position, the magnet is arranged to expose the substrate to a magnetic field in-situ within the chamber volume.

In another aspect, a semiconductor processing system is provided. The semiconductor processing system includes a first process chamber and a second process chamber, the first process chamber and the second process chamber each include: a chamber body defining a chamber volume; a pedestal having a heater, the pedestal being movable within the chamber volume between a transfer position and a process position, and, when the pedestal is in the process position, the pedestal at least partially defines a process cavity; and an electromagnet coupled with the chamber body below the process cavity. The semiconductor processing system also includes a computing system configured to: cause the first process chamber to deposit a magnetic layer onto a substrate disposed on the pedestal of the first process chamber; cause, with the pedestal of the first process chamber in the transfer position, the heater of the first process chamber to heat the substrate and the electromagnet of the first process chamber to expose the substrate to a magnetic field in-situ within the chamber volume of the first process chamber; cause the substrate to be transferred to the second process chamber; cause the second process chamber to deposit a dielectric layer onto the magnetic layer of the substrate disposed on the pedestal of the second process chamber; and cause, with the pedestal of the second process chamber in the transfer position, the heater of the second process chamber to heat the substrate and the electromagnet of the second process chamber to expose the substrate to a magnetic field in-situ within the chamber volume of the second process chamber.

In yet another aspect, a method of processing a semiconductor is provided. The method includes: processing a substrate disposed on a pedestal, the substrate being processed within a processing cavity defined at least in part by the pedestal when the pedestal is arranged in a process position; moving the pedestal from the process position to a transfer position within a chamber volume defined by a chamber body; heating the substrate using a heater disposed on or within the pedestal; and exposing, with the pedestal in the transfer position and the heater heating the substrate, the substrate to a magnetic field produced by a magnet arranged below the process cavity so as to magnetically anneal the substrate in-situ within the chamber volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic cross-sectional view of a process chamber and depicts a pedestal in an upper process position, according to embodiments of the present disclosure.

FIG. 2 is a schematic cross-sectional view of the process chamber of FIG. 1 and depicts the pedestal in a lowered transfer position, according to embodiments of the present disclosure.

FIG. 3 shows a substrate arranged as a magnetic film stack, according to embodiments of the present disclosure.

FIG. 4 is a schematic cross-sectional view of a process chamber, according to embodiments of the present disclosure.

FIG. 5 is a schematic diagram of a control circuit for selectively activating an electromagnet of a process chamber, according to embodiments of the present disclosure.

FIGS. 6A and 6B depict an example magnet for a process chamber, according to embodiments of the present disclosure.

FIG. 7 is a schematic diagram of a semiconductor processing system, according to embodiments of the present disclosure.

FIG. 8 is a flow diagram for a method of processing a substrate using a process chamber, according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides a physical vapor deposition (PVD) process chamber having features that enable in-situ magnetic annealing and bow control for magnetic film stacks, such as magnetic film stacks having alternating magnetic and dielectric layers stacked on a base layer. Magnetic film stacks can be used for Integrated Voltage Regulator (IVR) applications, for example.

In one aspect, a process chamber having features that enable in-situ magnetic annealing and bow control for magnetic film stacks is provided. The process chamber can include a chamber body defining a chamber volume. The process chamber can also include a pedestal having a heater arranged to heat a substrate disposed on the pedestal. The pedestal is movable within the chamber volume between a first position and a second position, or stated differently, between an upper process position and a lower transfer position. When the pedestal is in the process position, the pedestal at least partially defines a process cavity in which the substrate is processed via deposition. The process chamber further includes a magnet coupled with the chamber body below the process cavity. With the pedestal in the transfer position and the heater heating the substrate, the magnet is arranged to expose the substrate to a magnetic field in-situ within the chamber volume. In this regard, heat treatment for bow management and magnetic annealing for good magnetic properties of the substrate can be achieved in-situ (i.e., within the chamber volume), and at the same time. This can advantageously provide increased fabrication efficiency and throughput, among other benefits. For instance, the need to transfer a substrate to a heat treatment chamber or an ex-situ magnetic annealing tool can be eliminated or reduced.

In some aspects, the magnet can be an electromagnet that can be selectively activated to produce a magnetic field, such as when the pedestal is in the transfer position. The electromagnet can be deactivated during deposition processing of the substrate, e.g., to avoid stray magnetic field from affecting the plasma within the process cavity. This can advantageously avoid process drift. In other aspects, the magnet can be a permanent magnet, such as a permanent diametrically magnetized ring magnet. With an electromagnet or a permanent magnet coupled with the chamber body, the substrate can be exposed to a magnetic field in-situ to align the magnetic domains of the magnetic film stack. And, as noted above, the heater can heat the substrate at the same time to control the stress/bowing/warpage of the magnetic film stack. Accordingly, a magnetic film stack can be fabricated with low magnetic coercivity, low magnetic saturation, and high magnetic anisotropy, while also having low film stress/bowing. Example process chambers are described below with reference to the drawings.

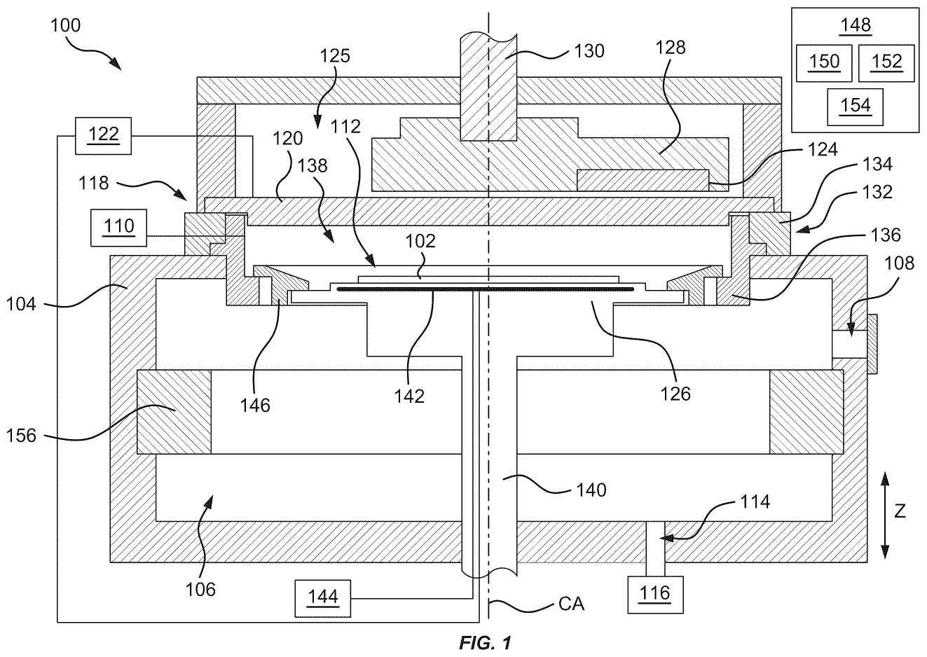

FIG. 1 illustrates a schematic cross-sectional view of an exemplary physical vapor deposition (PVD) process chamber 100 (e.g., a sputter process chamber) suitable for sputter depositing materials onto a baser layer or on a layer stacked on the base layer, e.g., to form a substrate 102. In some embodiments, the substrate 102 can be formed as a magnetic film stack having alternating magnetic and dielectric layers stacked on a base layer, for example. The process chamber 100 can be used to deposit the magnetic layers of the substrate 102 and another PVD process chamber (e.g., a same or similarly configured process chamber) can be used to deposit the dielectric layers of the substrate 102, or vice versa. Further, for reference, the process chamber 100 defines a Z-direction, which is a vertical direction in the depicted embodiment of FIG. 1. The process chamber 100 can also define a central axis CA, which is parallel to the Z-direction.

As illustrated in FIG. 1, the process chamber 100 includes a chamber body 104 defining a chamber volume 106. The chamber body 104 has sidewalls and a bottom wall. The dimensions of the chamber body 104 and related components of the process chamber 100 depicted in FIG. 1 are not limiting. The chamber body 104 may be fabricated from aluminum or other suitable materials. An access port 108 is formed through the sidewall of the chamber body 104. The access port 108 provides ingress and egress of the substrate 102 into and out of the chamber volume 106. In this regard, the access port 108 facilitates the transfer of the substrate 102 into and out of the process chamber 100. The access port 108 can be coupled to a transfer chamber and/or other chambers of a semiconductor processing system, e.g., by a transfer robot or other suitable transfer mechanism.

A gas source 110 is arranged to supply process gases into a process cavity 112. In one embodiment, process gases may include inert gases, non-reactive gases, and reactive gases, if necessary. Examples of process gases that may be provided by the gas source 110 include, but are not limited to, argon gas (Ar), helium gas (He), neon gas (Ne), nitrogen gas (N2), fluorine gas (F2), oxygen gas (O2), hydrogen gas (H2), H2O in vapor form, methane (CH4), carbon monoxide (CO), and/or carbon dioxide (CO2), among others. In one embodiment, a mass flow controller (MFC) (not shown) is coupled to the gas source 110 to finely and precisely control of the flow of gases.

A pumping port 114 is formed through the bottom wall of the chamber body 104. A pumping device 116 is coupled to the process cavity 112 to evacuate and control the pressure therein. A pumping system and chamber cooling design enables high base vacuum (e.g., about 1×10−8 Torr or less) and low rate-of-rise (e.g., about 1,000 mTorr/min) at temperatures suited to thermal needs, e.g., about −25 degrees Celsius to about 500 degrees Celsius. The pumping system is designed to provide precise control of process pressure, which is a parameter for refractive index (RI) control and tuning.

A chamber lid assembly 118 is mounted on the top of the chamber body 104. The chamber lid assembly 118 includes a target 120. The target 120 provides a material source that can be sputtered and deposited onto the surface of the substrate or another film of the substrate 102 during a PVD process. The target 120 can serve as the cathode of the plasma circuit during DC sputtering. The target 120, or target plate, can be fabricated from a material utilized for a deposition layer, or elements of the deposition layer to be formed in the process chamber 100. A high voltage power supply, such as a power source 122, is connected to the target 120 to facilitate sputtering materials from the target 120. In some embodiments, the target 120 can be fabricated from a material containing silicon (Si), titanium (Ti), tantalum (Ta), hafnium (Hf), tungsten (W), cobalt (Co), nickel (Ni), copper (Cu), aluminum (Al), alloys thereof, or combinations thereof and the like. The spacing between the target 120 and a pedestal 126 can be maintained between about 50 mm to about 350 mm, for example, about 55 mm. It is contemplated that the dimension, shape, materials, configuration and diameter of the target 120 may be varied for specific process or substrate requirements. In one embodiment, the target 120 may further include a backing plate having a central portion bonded and/or fabricated by a material desired to be sputtered onto the base layer or other layer stacked on the base layer. The target 120 can also include adjacent tiles or segmented materials that together form the target 120.

A magnetron 124 can be mounted above the target 120, which can be moved about within a reservoir 125 to enhance efficient sputtering materials from the target 120 during processing. The magnetron 124 can be moved relative to the target 120 in a desired pattern by an epicyclical gear system 128 to facilitate process control and tailored film properties while ensuring consistent target erosion and uniform deposition of films across the substrate 102. The epicyclical gear system 128 can include a sun gear and one or more follower or planetary gears that revolve about the sun gear. The epicyclical gear system 128 can be driven by one or more motors (not shown) via one or more rotatably drivable shafts 130. In other embodiments, the magnetron 124 can be a linear magnetron, a serpentine magnetron, a spiral magnetron, a double-digitated magnetron, a rectangularized spiral magnetron, among others.

The chamber lid assembly 118 can also include and a ground shield assembly 132. The ground shield assembly 132 includes a ground frame 134 and a ground shield 136. The ground shield assembly 132 can also include other shield members. The ground shield 136 is coupled to the ground frame 134 defining an upper processing region 138 below the central portion of the target 120 in the process cavity 112. The ground frame 134 electrically insulates the ground shield 136 from the target 120 while providing a ground path to the chamber body 104 of the process chamber 100 through the sidewalls. The ground shield 136 constrains plasma generated during processing within the upper processing region 138 and dislodges target source material from the confined central portion of the target 120, thereby allowing the dislodged target source to be mainly deposited on the substrate or other layer stacked thereon rather than chamber sidewalls. In some embodiments, the ground shield 136 may be formed by one or more work-piece fragments and/or a number of these pieces bonded by processes known in the art, such as welding, gluing, high pressure compression, etc.

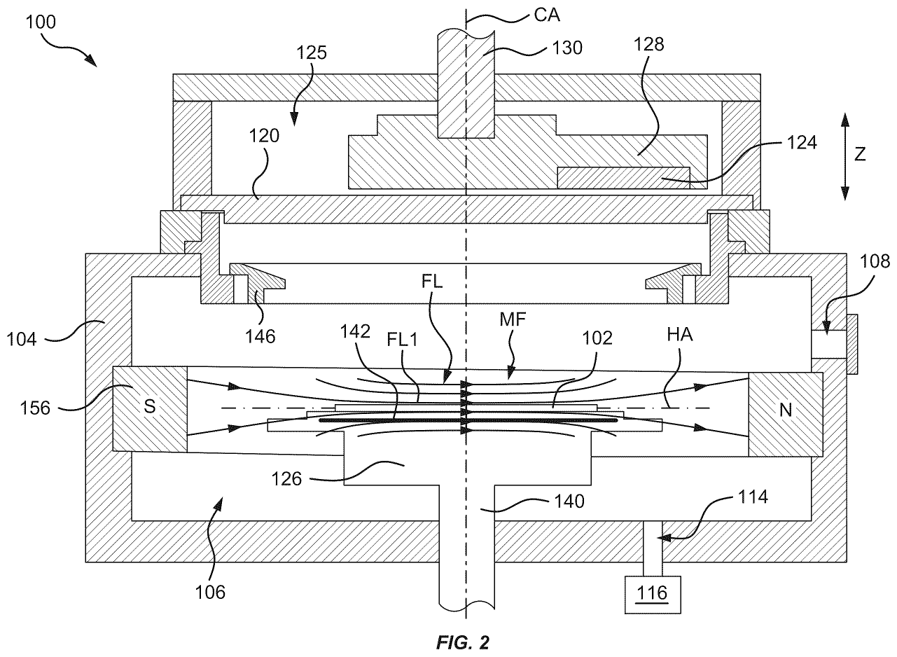

The substrate 102 can be disposed on the pedestal 126 as depicted in FIG. 1. The pedestal 126, or substrate support, can be formed of single plate or can be formed by a multiple plates, e.g., a support plate and a sealing plate. The pedestal 126 is coupled with a shaft 140 extending through the bottom wall of the chamber body 104. The shaft 140 can be coupled with a lift mechanism (not shown), which can include a drive motor arranged to move a carriage coupled with the shaft 140. The lift mechanism is configured to move the pedestal 126 within the chamber volume 106 along the Z-direction, e.g., between a first position and a second position, or stated differently, between an upper process position and a lower transfer position. In FIG. 1, the pedestal 126 is in the process position (the first position). When the pedestal 126 is in the process position, the pedestal 126 at least partially defines the process cavity 112, sealing the process cavity 112 from the lower portion of the chamber volume 106. In FIG. 2, which depicts another schematic cross-sectional view of the process chamber 100, the pedestal 126 is in the transfer position (the second position). In the transfer position, the substrate 102 can be moved into or out of the process chamber 100, e.g., by way of the access port 108. In some embodiments, bellows (not shown) can circumscribe the shaft 140 and can be coupled to the pedestal 126 to provide a flexible seal therebetween, thereby maintaining vacuum integrity of the process cavity 112.

The pedestal 138 has a heater 142 arranged to heat the substrate 102, e.g., before, during, or after a deposition process. The heater 142 can be an electro-static chuck (ESC), for example. The ESC can use the attraction of opposite charges to hold both insulating and conducting substrates for PVD processes and is powered by a DC power supply 144. The ESC can include an electrode embedded within a dielectric body. The DC power supply 144 can provide a DC chucking voltage of about 200 volts to about 2000 volts to the electrode. The DC power supply 144 can also include a system controller for controlling the operation of the electrode by directing a DC current to the electrode for chucking and de-chucking the substrate 102. The temperature of the heater 142 can be controlled to a predetermined temperature and/or can be varied according to heating profile, e.g., by changing the electric current provided to the electrode for resistance-type heating.

In some embodiments, the heater 142 can be arranged as a high temperature ESC, or HTSEC, e.g., operating in a temperature range of about 200 degrees Celsius to about 500 degrees Celsius, to ensure fast and uniform heating of the substrate 102. In other embodiments, the heater 142 can be arranged to operate in other temperature ranges. Accordingly, in some embodiments, the heater 142 can be arranged as a mid-temperature ESC, or MTESC, operating in a temperature range of about 100 degrees Celsius to about 200 degrees Celsius. In yet other embodiments, the heater 142 can be arranged as other high temperature ESCs, such as a high temperature biasable or high temperature high uniformity ESC (HTBESC or HTHUESC).

As further depicted in FIG. 1, a chamber shield 146 is held by the ground shield 136. When the pedestal 126 is raised to the process position for processing the substrate 102, an outer flange of the pedestal 126 engages the chamber shield 146. In this way, the pedestal 126 is configured to confine deposition of source material sputtered from the target 120 to a desired portion of the substrate 102 when in the process position. When the pedestal 126 is lowered to the transfer position, the pedestal 126 disengages from the chamber shield 146. To transfer the substrate 102 out of the process chamber 100, lift pins (not shown) can be moved through the pedestal 126 to lift the substrate 102 above the pedestal 126 to facilitate access to the substrate 102 by a transfer robot or other suitable transfer mechanism. The transfer robot can retrieve the substrate 102 by way of the access port 108.

A computing system 148 is arranged to control the various controllable devices of the process chamber 100. The computing system 148 includes one or more processors 150, one or more non-transitory memory devices 152, and support circuits 154, which can be embodied in one or more controllers, computing devices, etc. The computing system 148 is utilized to control the process sequence, regulating the gas flows from the gas source 110 into the process chamber 100 and controlling ion bombardment of the target 120. The one or more processors 150 can execute software routines or programs stored in the non-transitory memory devices 152, such as random access memory, read only memory, or other form of digital storage. The support circuits 154 are coupled to the one or more processors 150 and may comprise cache, clock circuits, input/output subsystems, power supplies, and the like. The software routines or programs, when executed by the one or more processors 150, can cause the one or more processors 150 to perform operations, such as an operation that controls the process chamber 100. The software routines may also be stored and/or executed by components located remotely from the process chamber 100.

During processing, material is sputtered from the target 120 and deposited on the surface of the substrate 102. The target 120 and the pedestal 126 can be biased relative to each other by the power source 122 to maintain a plasma formed from the process gases supplied by the gas source 110. The ions from the plasma are accelerated toward and strike the target 120, causing target material to be dislodged from the target 120. The dislodged target material and reactive process gases together form a layer on the substrate 102 with desired compositions. RF, DC or fast switching pulsed DC power supplies or combinations thereof provide tunable target bias for precise control of sputtering composition and deposition rates.

After the process gas is introduced into the process chamber 100, the gas is energized to form plasma. A plasma is commonly formed from an inert gas, such as argon, before a reactive gas is introduced into the process chamber 100. An antenna, such as one or more inductor coils, may be provided adjacent the process chamber 100. An antenna power supply may power the antenna to inductively couple energy, such as RF energy, to the process gas to form plasma in a process zone in the process chamber 100. Alternatively, or in addition, process electrodes comprising a cathode below the substrate 102 and an anode above the substrate 102 may be used to couple RF power to generate plasma. The operation of the antenna power supply may be controlled by the computing system 148 that also controls the operation of other components in the process chamber 100.

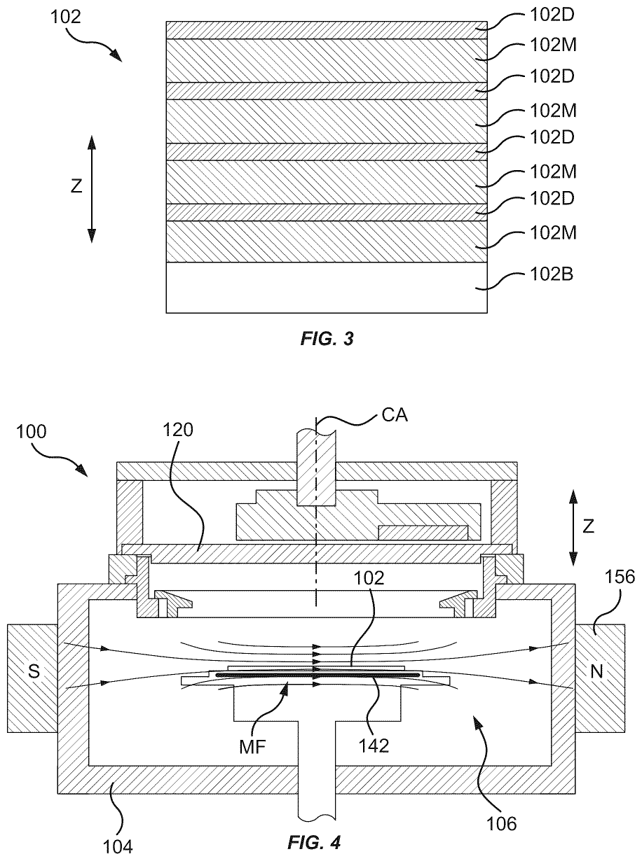

As noted previously, in some embodiments, the substrate 102 can be formed by the process chamber 100 as a magnetic film stack having alternating magnetic and dielectric layers stacked on a substrate. The process chamber 100 can be used to deposit the magnetic layers of the substrate 102 and another PVD process chamber (e.g., a same or similarly configured process chamber) can be used to deposit the dielectric layers of the substrate 102, or vice versa. An example substrate 102 formed as a magnetic film stack is provided below with reference to FIG. 3.

FIG. 3 shows the substrate 102 arranged as a magnetic film stack. As depicted, the substrate 102 has a base layer 102B, magnetic layers 102M, and dielectric layers 102D. The magnetic layers 102M and dielectric layers 102D, or magnetic and dielectric films, are stacked on the base layer 102B and alternate along the Z-direction, with the dielectric layers 102D each being stacked on a respective one of the magnetic layers 102M. Generally, it is desirable for a magnetic film stack to have low magnetic coercivity, low magnetic saturation, and high magnetic anisotropy. It is also generally desirable to have low film stress/bowing.

With reference again to FIGS. 1 and 2, the process chamber 100 includes features for providing in-situ (i.e., in chamber volume 106) magnetic annealing of the substrate 102, e.g., for achieving good magnetic properties, as well bow management of the layers. In at least some embodiments, as shown in FIGS. 1 and 2, the process chamber 100 can include an electromagnet 156. In at least some embodiments, the electromagnet 156 is an annular ring, e.g., centered on the central axis CA. In other embodiments, the electromagnet 156 can be formed by a plurality of circumferentially-arranged segments, e.g., arranged circumferentially around the central axis CA. The electromagnet 156 can be formed of a plurality of windings wrapped around an annular core, for example. The core can be formed of a ferrite material, for example.

The electromagnet 156 is coupled with the chamber body 104 below the process cavity 112, or rather, in a lower portion of the chamber body 104. The electromagnet 156 can be arranged at or below the access port 108 defined by the chamber body 104, e.g., along the Z-direction. For the depicted embodiment of FIGS. 1 and 2, the electromagnet 156 is disposed, at least in part, within the chamber volume 106. The electromagnet 156 can be mounted to interior surfaces of the sidewalls of the chamber body 104, for example. In other embodiments, the electromagnet 156 can be embedded within the sidewalls of the chamber body 104. In yet other embodiments, as shown in FIG. 4, the electromagnet 156 can be disposed external to the chamber volume 106. For instance, the electromagnet 156 can be coupled with exterior surfaces of the sidewalls of the chamber body 104.

As shown in FIG. 2, with the pedestal 126 in the transfer position, the electromagnet 156 is arranged to selectively expose the substrate 102 to a magnetic field MF in-situ within the chamber volume 106. In this regard, the electromagnet 156 is arranged to magnetically anneal the substrate 102 in-situ within the chamber volume 106, which can align the magnetic domains of the magnetic layers 102M (FIG. 3), or rather, align the magnetic dipole of a deposited magnetic film. Aligning the magnetic domains can advantageously provide low magnetic coercivity, low magnetic saturation, and high magnetic anisotropy of the substrate 102, or magnetic film stack in this example. Moreover, by having the magnetic annealing occur outside of the process cavity 112, the electromagnet 156 does not affect or only minimally affects PVD deposition within the process cavity 112.

In some embodiments, the magnetic field MF produced by the electromagnet 156 has a uniform field along the substrate 102. That is, field lines FL of the magnetic field MF (or B-field lines) generally traverse in one direction from one semi-annular section of the electromagnet 156 to the other (e.g., from a south pole S to a north pole N in a diametrically magnetized electromagnet as depicted in FIG. 2). In some embodiments, the electromagnet 156 can be coupled with the chamber body 104 so that, when the pedestal 126 is in the transfer position and the electromagnet 156 selectively exposes the substrate 102 to the magnetic field MF in-situ within the chamber volume 106 as shown in FIG. 2, at least one field line FL1 of a plurality of field lines FL of the magnetic field MF is arranged substantially parallel to a horizontal axis HA of the substrate 102 as the at least one field line FL1 traverses through or by a center point of the substrate 102. The central axis CA extends through the center point of the substrate 102 in this example. Moreover, the horizontal axis HA is perpendicular to the Z-direction in this example. As used herein, a line is “substantially parallel” to the horizontal axis HA when it is within five degrees (5°) of the horizontal axis HA.

In some aspects, the electromagnet 156 is arranged to selectively expose the substrate 102 to the magnetic field MF in-situ within the chamber volume 106 while the heater 142 is heating the substrate 102. In this regard, magnetic annealing and bow/stress control of the films can occur at the same time. Advantageously, simultaneously performing magnetic annealing and bow management in-situ can facilitate improved throughput of substrates processed. In some examples, while the substrate 102 is exposed to the magnetic field MF by the electromagnet 156, the heater 142 can heat the substrate 102 within a temperature range between about 175° C. and 250° C. Heat treatment of the substrate 102 reduces the compressive stress on the deposited films. Bow and stress of the substrate 102 can be controlled by tuning the heater 142 to a desired temperature.

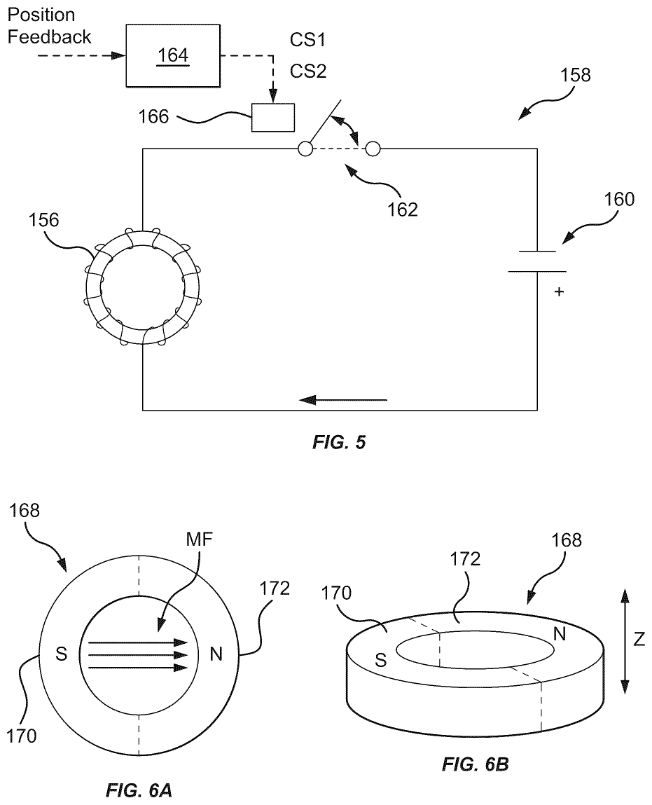

In some embodiments, as shown in FIG. 5, the electromagnet 156 can be a component of a control circuit 158. The control circuit 158 can include features that facilitate selective activation of the electromagnet 156, e.g., when the pedestal 126 is in the transfer position as in FIGS. 2 and 4. As depicted in FIG. 5, the control circuit 158 can include a power source 160 (e.g., a DC power source), one or more switches (represented by switch 162 in FIG. 5), and a controller 164 arranged to actuate the switch 162. The controller 164 can be a component of the computing system 148 (FIG. 1). By actuating the switch 162 to a closed position, electrical power from the power source 160 can be provided to the electromagnet 156, which can cause the electromagnet 156 to produce the magnetic field MF (FIGS. 2 and 4).

As depicted in FIG. 5, when the controller 164 receives feedback indicating a position of the pedestal 126 (FIGS. 1 and 2) in the transfer position, among other possible feedback, the controller 164 can route one or more control signals CS1 to a switch driver 166 associated with switch 162. The switch 162 can be a normally-open switch, for example. Accordingly, when the switch driver 166 receives the one or more control signals CS1, the switch driver 166 can cause the switch 162 to move to a closed position to close the circuit. In this way, electric current can flow from the power source 160 to the electromagnet 156. Thus, the electromagnet 156 can be activated to produce a magnetic field for magnetically annealing the substrate 102 (FIGS. 2 and 4).

When the pedestal 126 is in the process position as shown in FIG. 1 (for deposition of a layer on the substrate 102), or when magnetic annealing is not needed or not the current sub-process in progress, the electromagnet 156 can be deactivated. For instance, as shown in FIG. 5, the controller 164 can send one or more control signals CS2 to the switch driver 166 to open the switch 162, which opens the circuit and ceases the flow of electric current to the electromagnet 156. In this way, the electromagnet 156 can be selectively deactivated, which is advantageous in that the electromagnet 156 does not affect the PVD deposition within the process cavity 112 and the process kits need not any additional components or design changes to account for a magnetic field produced by the electromagnet 156.

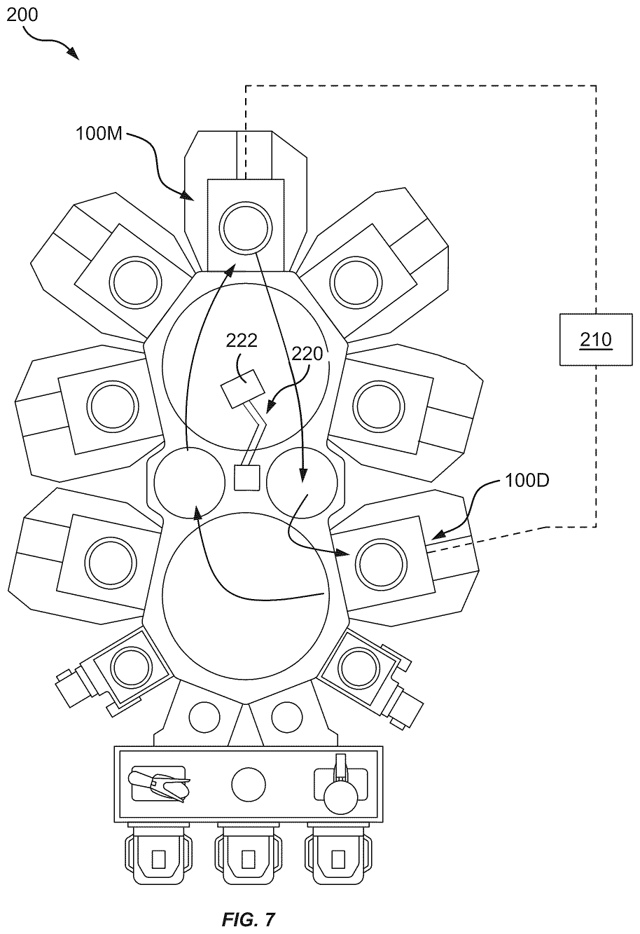

In some other embodiments, instead of an electromagnet, the process chamber 100 can include a permanent magnet. FIGS. 6A and 6B depict an example permanent magnet 168 that can be incorporated into a process chamber, such as the process chamber 100 of FIGS. 1 and 2 or FIG. 4. The permanent magnet 168 can be a permanent diametrically magnetized ring magnet. In this regard, the ring has two semi-annular sections, including a south pole semi-annular section 170 and a north pole semi-annular section 172. The semi-annular sections 170, 172 can be arranged in a diametric arrangement such that the magnetic field MF produced has uniform field lines, e.g., as shown in FIG. 6A. A substrate can be exposed to such uniform field lines, e.g., to align the magnetic domains thereof. The permanent magnet 168 can be arranged at least in part within a chamber volume (similar to the position of the electromagnet 156 in FIGS. 1 and 2), can be embedded within the sidewalls of a chamber body, or can be arranged external to the chamber volume of a process chamber (similar to the position of the electromagnet 156 in FIG. 4).

FIG. 7 is a schematic diagram of a semiconductor processing system 200, according to embodiments of the present disclosure. As depicted in FIG. 7, the semiconductor processing system 200 can include at least a first process chamber 100M and a second process chamber 100D, or rather a magnetic film PVD chamber and a dielectric film PVD chamber. In this regard, the semiconductor processing system 200 is configured to fabricate a substrate formed as a magnetic film stack, such as the magnetic film stack depicted in FIG. 3.

The first process chamber 100M and the second process chamber 100D each include a chamber body defining a chamber volume; a pedestal having a heater, with the pedestal being movable within the chamber volume between a transfer position and a process position, and, when the pedestal is in the process position, the pedestal at least partially defines a process cavity. The first process chamber 100M and the second process chamber 100D each further include an electromagnet coupled with the chamber body below the process cavity. In this manner, the first process chamber 100M and the second process chamber 100D can each be configured as the process chamber 100 in FIGS. 1 and 2 or FIG. 4.

The semiconductor processing system 200 further includes a computing system 210 configured to implement a fabrication operation. The computing system 210 includes one or more processors, one or more non-transitory memory devices, and support circuits, which can be embodied in one or more computing devices. The computing system 210 can be configured in a similar manner as the computing system 148 of FIG. 1, for example. The one or more processors of the computing system 210 can access computer code or instructions stored on one or more non-transitory medium, and can execute the computer code to perform an operation, such as a fabrication operation. The computing system 210 can be communicatively coupled with the computing systems of the process chambers, among other components, e.g., by way of wired and/or wireless communication links.

In implementing the fabrication operation, the computing system 210 is configured to cause the first process chamber 100M to deposit a magnetic layer onto a substrate disposed on the pedestal of the first process chamber 100M. In causing the first process chamber 100M to deposit the magnetic layer onto the substrate disposed on the pedestal of the first process chamber 100M, the computing system 210 is configured to cause the electromagnet of the first process chamber 100M to deactivate so as not to produce a magnetic field. In this way, the electromagnet does not affect deposition of the magnetic layer. The computing system 210 is also configured to cause, with the pedestal of the first process chamber 100M in the transfer position, the heater of the first process chamber to heat the substrate and the electromagnet of the first process chamber 100M to expose the substrate to a magnetic field in-situ within the chamber volume of the first process chamber. In this regard, after deposition of the magnetic layer, the substrate with the newly formed magnetic layer can be magnetically annealed for magnetic alignment and heated for bow control management of the layers in-situ, or rather, within the first process chamber 100M. Accordingly, the need for transferring the substrate to a heat treatment chamber and/or ex-situ magnetic annealing chamber before transferring the substrate to the second process chamber 100D is eliminated or reduced. This can advantageously increase fabrication efficiency and throughput.

The computing system 210 is further configured to cause the substrate to be transferred to the second process chamber 100D. For example, a transfer robot 220 having a robotic arm 222 can transfer the substrate from the first process chamber 100M to the second process chamber 100D. In some embodiments, the substrate can be cooled for a predetermined time before being transferred from the first process chamber 100M to the second process chamber 100D.

With the substrate transferred to the second process chamber 100D, the computing system 210 is further configured to cause the second process chamber 100D to deposit a dielectric layer onto the magnetic layer of the substrate disposed on the pedestal of the second process chamber 100D. In causing the second process chamber 100D to deposit the dielectric layer (e.g., an aluminum oxide) onto the substrate disposed on the pedestal of the second process chamber 100D, the computing system 210 is configured to cause the electromagnet of the first process chamber 100M to deactivate so as not to produce a magnetic field. In this way, the electromagnet does not affect deposition of the dielectric layer. The computing system 210 is configured to cause, with the pedestal of the second process chamber 100D in the transfer position, the heater of the second process chamber 100D to heat the substrate and the electromagnet of the second process chamber 100D to expose the substrate to a magnetic field in-situ within the chamber volume of the second process chamber 100D. Accordingly, after deposition of the dielectric layer, the substrate with the newly formed dielectric layer can be magnetically annealed for magnetic alignment and heated for bow control management of the layers in-situ, or rather, within the second process chamber 100D. Accordingly, the need for transferring the substrate to a heat treatment chamber and/or ex-situ magnetic annealing chamber before transferring the substrate back to the first process chamber 100M for the next magnetic layer is eliminated or reduced. This can advantageously further increase fabrication efficiency and throughput.

After magnetically annealing and heat treating for bow management in-situ within the second process chamber 100D, the substrate can be transferred back to the first process chamber 100M for the next magnetic layer by the transfer robot 220. In some embodiments, the substrate can be cooled for a predetermined time before being transferred back to the first process chamber 100M. The process described above can be iterated to form a substrate with a desired number of stacked layers.

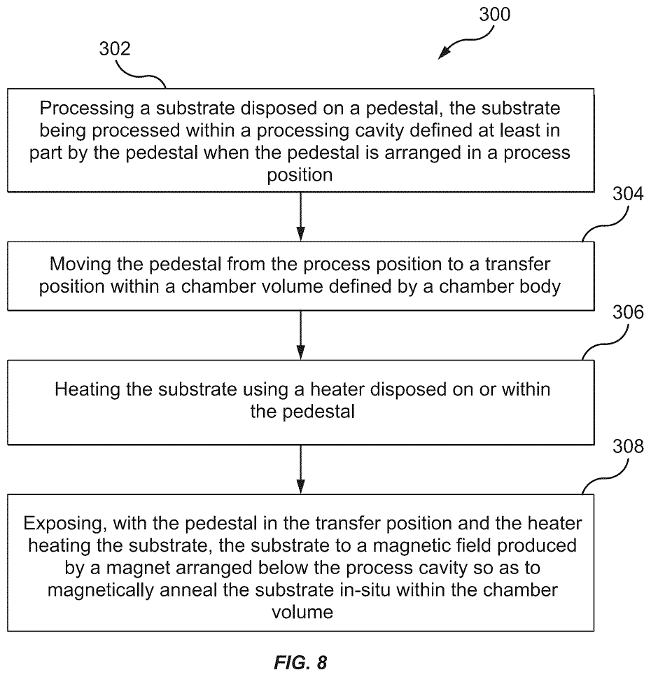

FIG. 8 is a flow diagram for a method 300 of processing a substrate using a process chamber, such as any of the process chambers disclosed herein.

At 302, the method 300 can include processing a substrate disposed on a pedestal, the substrate being processed within a processing cavity defined at least in part by the pedestal when the pedestal is arranged in a process position. For instance, during processing at 302, a layer can formed on a substrate or a layer stacked thereon via PVD.

At 304, the method 300 can include moving the pedestal from the process position to a transfer position within a chamber volume defined by a chamber body. For instance, a lift mechanism can move the pedestal downward from the process position to the transfer position. The lift mechanism can include a drive motor that drives a carriage along a track. The carriage can be coupled with a shaft coupled to the pedestal.

At 306, the method 300 can include heating the substrate using a heater disposed on or within the pedestal. For instance, the substrate can be heated during processing at 302 and can continue to be heated, e.g., during 304, and during 308 as described below. If the heater is not already activated to heat the substrate, the heater can be activated. Heating the substrate with the heater can provide bow control management of the layers of the substrate. In some implementations, the heater can be arranged as a high temperature ESC, or HTSEC, e.g., operating in a temperature range of about 200 degrees Celsius to about 500 degrees Celsius.

At 308, the method 300 can include exposing, with the pedestal in the transfer position and the heater heating the substrate, the substrate to a magnetic field produced by a magnet arranged below the process cavity so as to magnetically anneal the substrate in-situ within the chamber volume. Accordingly, magnetic annealing and heat treatment can occur in-situ within the chamber volume. For instance, the magnet can be an electromagnet. With the heater heating the substrate for bow control management, the electromagnet can selectively expose the substrate to a magnetic field. As one example, electric current can be supplied to windings or coils of the electromagnet, causing the electromagnet to produce the magnetic field. In some implementations, the field lines or B-field of the magnetic field can be uniform along the substrate. The electromagnet can be energized to be diametrically magnetized so as to produce the uniform field. The electromagnet can produce a magnetic field so that at least one field line is substantially parallel with a horizontal axis of the substrate. By exposing the substrate to a magnetic field, particularly where the substrate is a magnetic film stack, the substrate can advantageously have low magnetic coercivity, low magnetic saturation, and high magnetic anisotropy. As noted above, the heater can provide bow control management.

In some implementations, when the film is undergoing deposition at 302, the electromagnet can be turned off to avoid stray magnetic field from affecting the plasma within the process cavity. This can advantageously avoid process drift.

In yet other implementations, the magnet can be a permanent magnet, such as a diametrically magnetized ring magnet. The permanent magnet can be coupled with a chamber body of the process chamber and arranged below the process cavity, such as at or below an access port defined by the chamber body, wherein the access port provides ingress and egress of the substrate into and out of the chamber volume.

In some implementations, the processing, the moving, the heating, and the exposing at 302, 304, 306, and 308 occur at a first process chamber. In such implementations, the method further includes transferring the substrate to a second process chamber; processing the substrate disposed on a pedestal of the second process chamber, the substrate being processed within a processing cavity defined at least in part by the pedestal of the second process chamber when the pedestal is arranged in a process position; moving the pedestal of the second process chamber from the process position to a transfer position within a chamber volume defined by a chamber body of the second process chamber; heating the substrate using a heater disposed on or within the pedestal of the second process chamber; and exposing, with the pedestal of the second process chamber in the transfer position and the heater of the second process chamber heating the substrate, the substrate to a magnetic field produced by a magnet arranged below the process cavity so as to magnetically anneal the substrate in-situ within the chamber volume of the second process chamber. In addition, in such implementations, processing the substrate disposed on the pedestal of the first process chamber at 302 can include depositing a magnetic layer on the substrate and processing the substrate disposed on the pedestal of the second process chamber can include depositing a dielectric layer on the substrate. In this way, a magnetic film stack up can be formed.

While the foregoing is directed to embodiments of the present disclosure, other and further embodiments of the disclosure may be devised without departing from the basic scope thereof, and the scope thereof is determined by the claims that follow.

What is claimed is:

1. A process chamber, comprising:
a chamber body defining a chamber volume;
a pedestal having a heater arranged to heat a substrate disposed on the pedestal, the pedestal being movable within the chamber volume between a first position and a second position, and, when the pedestal is in the first position, the pedestal at least partially defines a process cavity; and
a magnet coupled with the chamber body below the process cavity,
wherein, with the pedestal in the second position, the magnet is arranged to expose the substrate to a magnetic field in-situ within the chamber volume.

2. The process chamber of claim 1, wherein the magnet is an electromagnet that is arranged to selectively expose, with the pedestal in the second position, the substrate to the magnetic field in-situ within the chamber volume.

3. The process chamber of claim 2, wherein the electromagnet is arranged to selectively expose the substrate to the magnetic field in-situ within the chamber volume while the heater is heating the substrate.

4. The process chamber of claim 2, wherein the magnetic field produced by the electromagnet has a uniform field along the substrate.

5. The process chamber of claim 2, wherein the electromagnet is coupled with the chamber body so that, when the pedestal is in the second position and the electromagnet selectively exposes the substrate to the magnetic field in-situ within the chamber volume, at least one field line of a plurality of field lines of the magnetic field is arranged substantially parallel to a horizontal axis of the substrate as the at least one field line traverses through a center point of the substrate.

6. The process chamber of claim 2, wherein the electromagnet is arranged to be selectively deactivated while the pedestal is in the first position.

7. The process chamber of claim 2, wherein the electromagnet is an annular ring.

8. The process chamber of claim 2, wherein the electromagnet has a plurality of circumferentially-arranged segments.

9. The process chamber of claim 2, wherein the electromagnet is a component of a control circuit, the control circuit comprising:
a power source;
one or more switches; and
a controller arranged to actuate the one or more switches so as to selectively provide electrical power from the power source to the electromagnet.

10. The process chamber of claim 1, wherein the magnet is disposed within the chamber volume.

11. The process chamber of claim 1, wherein the magnet is disposed external to the chamber volume.

12. The process chamber of claim 1, wherein the magnet is arranged at or below an access port defined by the chamber body, the access port providing ingress and egress of the substrate into and out of the chamber volume.

13. The process chamber of claim 1, wherein the substrate is a magnetic film stack having a substrate and at least one magnetic layer stacked thereon.

14. The process chamber of claim 1, wherein the magnet is a permanent diametrically magnetized ring magnet.

15. A semiconductor processing system, comprising:
a first process chamber and a second process chamber, the first process chamber and the second process chamber each comprising:
a chamber body defining a chamber volume;
a pedestal having a heater, the pedestal being movable within the chamber volume between a transfer position and a process position, and, when the pedestal is in the process position, the pedestal at least partially defines a process cavity; and
an electromagnet coupled with the chamber body below the process cavity; and
a computing system configured to:
cause the first process chamber to deposit a magnetic layer onto a substrate disposed on the pedestal of the first process chamber;
cause, with the pedestal of the first process chamber in the transfer position, the heater of the first process chamber to heat the substrate and the electromagnet of the first process chamber to expose the substrate to a magnetic field in-situ within the chamber volume of the first process chamber;
cause the substrate to be transferred to the second process chamber;
cause the second process chamber to deposit a dielectric layer onto the magnetic layer of the substrate disposed on the pedestal of the second process chamber; and
cause, with the pedestal of the second process chamber in the transfer position, the heater of the second process chamber to heat the substrate and the electromagnet of the second process chamber to expose the substrate to a magnetic field in-situ within the chamber volume of the second process chamber.

16. The semiconductor processing system of claim 15, wherein in causing the first process chamber to deposit the magnetic layer onto the substrate disposed on the pedestal of the first process chamber, the computing system is configured to cause the electromagnet of the first process chamber to deactivate.

17. The semiconductor processing system of claim 15, further comprising:
a transfer robot having a robotic arm arranged to transfer the substrate at least between the first process chamber and the second process chamber.

18. A method of processing a semiconductor, comprising:
processing a substrate disposed on a pedestal, the substrate being processed within a processing cavity defined at least in part by the pedestal when the pedestal is arranged in a process position;
moving the pedestal from the process position to a transfer position within a chamber volume defined by a chamber body;
heating the substrate using a heater disposed on or within the pedestal; and
exposing, with the pedestal in the transfer position and the heater heating the substrate, the substrate to a magnetic field produced by a magnet arranged below the process cavity so as to magnetically anneal the substrate in-situ within the chamber volume.

19. The method of claim 18, wherein the processing, the moving, the heating, and the exposing occur at a first process chamber, and wherein the method further comprises:
transferring the substrate to a second process chamber;
processing the substrate disposed on a pedestal of the second process chamber, the substrate being processed within a processing cavity defined at least in part by the pedestal of the second process chamber when the pedestal is arranged in a process position;
moving the pedestal of the second process chamber from the process position to a transfer position within a chamber volume defined by a chamber body of the second process chamber;
heating the substrate using a heater disposed on or within the pedestal of the second process chamber; and
exposing, with the pedestal of the second process chamber in the transfer position and the heater of the second process chamber heating the substrate, the substrate to a magnetic field produced by a magnet arranged below the process cavity so as to magnetically anneal the substrate in-situ within the chamber volume of the second process chamber.

20. The method of claim 19, wherein processing the substrate disposed on the pedestal of the first process chamber comprises depositing a magnetic layer on the substrate and processing the substrate disposed on the pedestal of the second process chamber comprises depositing a dielectric layer on the substrate.
